(19) United States
(12) Patent Application Publication
(10) Pub. No.: US 2011/0215734 A1
(43) Pub. Date: Sep. 8, 2011

(54) PWM PULSE GENERATING CIRCUIT, DEVICE HAVING THE SAME, AND PWM CONTROL METHOD

(75) Inventor: Yeon-Tack SHIM, Hwaseong-si (KR)

(73) Assignee: Samsung Electronics Co., Ltd, Suwon-si (KR)

(21) Appl. No.: 13/025,673

(22) Filed: Feb. 11, 2011

(30) Foreign Application Priority Data
Mar. 4, 2010 (KR) 2010-0019486

(51) Int. Cl. H05B 37/02; H03K 7/08; G09F 13/04

(52) U.S. Cl. 315/294; 332/109; 362/97.1

(57) ABSTRACT

Provided is a pulse width modulation (PWM) pulse generating circuit, a device including the circuit, and a PWM control method. The circuit includes a detector to detect the frequency of the PWM clock signal and output a frequency detection signal including whether the frequency of the PWM clock signal is higher than a reference frequency, and a PWM pulse signal output unit to generate a PWM pulse signal according to a data signal, the PWM clock signal, and the frequency detection signal. When the frequency detection signal includes that the frequency of the PWM clock signal is higher than the reference frequency, the PWM pulse signal output unit generates the PWM pulse signal having a predetermined allowable pulse width or a pulse with that is higher than the predetermined allowable pulse width.

### CROSS-REFERENCE TO RELATED APPLICATIONS

This application claims priority under 35 U.S.C. §119 to Korean Patent Application No. 10-2010-0019486 filed on Mar. 4, 2010, the disclosure of which is hereby incorporated by reference in its entirety.

### BACKGROUND

1. Field of the Invention

Embodiments of the present general inventive concept relate to a pulse width modulation (PWM) pulse generating circuit, a device having the circuit, and a PWM control method, which may provide the minimum pulse width of a PWM pulse.

2. Description of the Related Art

A pulse width modulation (PWM) pulse has been widely used to generate a control signal. However, when the control signal is generated using the PWM pulse, it may become necessary to measure the frequency of the PWM pulse. For example, when an analog circuit is driven using a PWM pulse, the minimum pulse width of the PWM pulse must be ensured to drive the analog circuit, and the frequency of the PWM pulse must be known to ensure the minimum pulse width of the PWM pulse.

### SUMMARY

Embodiments of the present general inventive concept provide a pulse width modulation (PWM) pulse generating circuit to generate a PWM pulse to provide the minimum pulse width.

Exemplary embodiments of the present general inventive concept may provide a device including the PWM pulse generating circuit.

Exemplary embodiments of the present general inventive concept may provide a PWM control method.

Additional features and utilities of the present general inventive concept will be set forth in part in the description which follows and, in part, will be obvious from the description, or may be learned by practice of the present general inventive concept.

Exemplary embodiments of the present general inventive concept may provide a PWM pulse generating circuit includes a detector to detect the frequency of the PWM clock signal and to output a frequency detection signal including whether the frequency of the PWM clock signal is higher than a reference frequency, and a PWM pulse signal output unit configured to generate a PWM pulse signal according to a data signal, the PWM clock signal, and the frequency detection signal. When the frequency detection signal indicates that the frequency of the PWM clock signal is higher than the reference frequency, the PWM pulse signal output unit generates the PWM pulse signal having a predetermined allowable pulse width or a pulse width that is higher than the predetermined allowable pulse width.

The detector may include an oscillator to generate a reference clock signal, a frequency detector to count the reference clock signal according to the PWM clock signal and to output frequency information on the PWM clock signal, and a determiner to receive the frequency information, compare the frequency information with the reference frequency, and output the frequency detection signal.

The determiner may determine that the frequency of the PWM clock signal is higher than the reference frequency when the frequency of the PWM clock signal becomes higher than a first reference frequency and higher than the reference frequency in a state where the frequency of the PWM clock signal is lower than the reference frequency. The determiner may determine that the frequency of the PWM clock signal is lower than the reference frequency when the frequency of the PWM clock signal becomes lower than a second reference frequency and lower than the reference frequency in a state where the frequency of the PWM clock signal is higher than the reference frequency. The determiner may output the frequency detection signal according to a determination result.

The determiner may set a plurality of reference frequencies to set a plurality of frequency ranges, compare the frequency information with each of the plurality of reference frequencies, and output the frequency detection signal that includes which one of the plurality of frequency ranges the frequency of the PWM clock signal belongs.

The PWM pulse signal output unit may include a PWM generator to receive the PWM clock signal and to output an internal PWM pulse signal having a duty ratio corresponding to the data signal, and a minimum pulse-width controller to output the internal PWM pulse signal as the PWM pulse signal when the frequency detection signal indicates that the frequency of the PWM clock signal is lower than the reference frequency or when the pulse width of the internal PWM pulse signal is greater than the predetermined allowable pulse width, adjust the pulse width of the internal PWM pulse signal to be equal to the predetermined allowable pulse width and output the adjusted internal PWM pulse signal as the PWM pulse signal when the frequency detection signal indicates that the frequency of the PWM clock signal is higher than the reference frequency and the pulse width of the internal PWM pulse signal is less than the predetermined allowable pulse width, and output the PWM pulse signal. Alternatively, the PWM pulse signal output unit may include an internal data generator to output the data signal as an internal data signal when the frequency detection signal indicates that the frequency of the PWM clock signal is lower than the reference frequency or when the pulse width of the PWM pulse signal to be generated according to the data signal is greater than the predetermined allowable pulse width and calculate the data signal so that the pulse width of the PWM pulse signal to be equal to the predetermined allowable pulse width and output the calculated data signal as the internal data signal when the frequency detection signal includes the frequency of the PWM clock signal is higher than the reference frequency and the pulse width of the PWM pulse signal to be generated according to the data signal is less than the predetermined allowable pulse width, and a PWM generator to receive the PWM clock signal and to generate the PWM pulse signal having a duty ratio corresponding to the internal data signal.

The PWM pulse generating circuit may further include a PWM clock generator to generate a PWM clock signal.

Exemplary embodiments of the present general inventive concept may also provide a device that includes a PWM clock generator to generate a PWM clock signal a detector to detect the frequency of the PWM clock signal and to output a frequency detection signal including whether the frequency of the PWM clock signal is higher than a reference frequency, a PWM pulse signal output unit to generate a PWM pulse signal in response to a data signal, the PWM clock signal, and the frequency detection signal, and an analog circuit to be driven according to the PWM pulse signal. When the frequency detection signal includes the frequency of the PWM clock signal is higher than the reference frequency, the PWM pulse signal output unit generates the PWM pulse signal having a predetermined allowable pulse width or a pulse width that is higher than the predetermined allowable pulse width.

The device may further include a backlight unit (BLU) including at least one light emitting diode (LED), and an LED power source to supply a power supply voltage to the at least one LED.

The analog circuit may vary a driving current supplied to the at least one LED according to the PWM pulse signal.

The detector may include an oscillator to generate a reference clock signal, a frequency detector to count the reference clock signal according to the PWM clock signal and output frequency information on the PWM clock signal, and a determiner to receive the frequency information, compare the frequency information with the reference frequency, and output the frequency detection signal.

The determiner may determine that the frequency of the PWM clock signal is higher than the reference frequency when the frequency of the PWM clock signal becomes higher than a first reference frequency and higher than the reference frequency in a state where the frequency of the PWM clock signal is lower than the reference frequency. The determiner may determine that the frequency of the PWM clock signal is lower than the reference frequency when the frequency of the PWM clock signal becomes lower than a second reference frequency and lower than the reference frequency in a state where the frequency of the PWM clock signal is higher than the reference frequency. Furthermore, the determiner may output the frequency detection signal according to a determination result.

The PWM pulse signal output unit may include a PWM generator to receive the PWM clock signal and output an internal PWM pulse signal having a duty ratio corresponding to the data signal, and a minimum pulse-width controller to output the internal PWM pulse signal as the PWM pulse signal when the frequency detection signal includes the frequency of the PWM clock signal is lower than the reference frequency or when the pulse width of the internal PWM pulse signal is greater than the predetermined allowable pulse width, to adjust the pulse width of the internal PWM pulse signal to be equal to the predetermined allowable pulse width and output the adjusted internal PWM pulse signal as the PWM pulse signal when the frequency detection signal includes that the frequency of the PWM clock signal is higher than the reference frequency and the pulse width of the internal PWM pulse signal is less than the predetermined allowable pulse width, and output the PWM pulse signal. Alternatively, the PWM pulse signal output unit of the device may include an internal data generator to output the data signal as an internal data signal when the frequency detection signal includes that the frequency of the PWM clock signal is lower than the reference frequency or when the pulse width of the PWM pulse signal to be generated according to the data signal is greater than the predetermined allowable pulse width and calculate the data signal so that the pulse width of the PWM pulse signal is equal to the predetermined allowable pulse width and to output the calculated data signal as the internal data signal when the frequency detection signal includes that the frequency of the PWM clock signal is higher than the reference frequency and the pulse width of the PWM pulse signal to be generated according to the data signal is less than the predetermined allowable pulse width, and a PWM generator to receive the PWM clock signal and to generate the PWM pulse signal having a duty ratio corresponding to the internal data signal.

Exemplary embodiments of the present general inventive concept may also provide a PWM control method of a device including a PWM clock generator to generate a PWM clock signal and a PWM pulse signal output unit to receive the PWM clock signal and to output a PWM pulse signal having a duty ratio corresponding to a data signal includes generating the PWM clock signal, detecting the frequency of the PWM clock signal, and generating the PWM pulse signal having a predetermined allowable pulse width or a pulse width that is higher than the predetermined allowable pulse width when the frequency of the PWM clock signal is higher than a reference frequency.

The method may further include setting an initial value of the frequency detection signal including whether the frequency of the PWM clock signal is higher than the reference frequency.

The detection of the frequency of the PWM clock signal may include determining that the frequency of the PWM clock signal is higher than the reference frequency when the frequency of the PWM clock signal becomes higher than a first reference frequency and higher than the reference frequency in a state where the frequency of the PWM clock signal is lower than the reference frequency, and determining that the frequency of the PWM clock signal is lower than the reference frequency when the frequency of the PWM clock signal becomes lower than a second reference frequency and lower than the reference frequency in a state where the frequency of the PWM clock signal is higher than the reference frequency.

The detection of the frequency of the PWM clock signal may include setting a plurality of reference frequencies to set a plurality of frequency ranges, comparing the frequency of the PWM clock signal with each of the plurality of reference frequencies, and determining to which one of the plurality of frequency ranges the frequency of the PWM clock signal belongs.

The generation of the PWM pulse signal may include inputting the PWM clock signal and generating an internal PWM pulse signal having a duty ratio corresponding to the data signal, and outputting the internal PWM pulse signal as the PWM pulse signal when the frequency of the PWM clock signal is lower than the reference frequency or when the pulse width of the internal PWM pulse signal is greater than the predetermined allowable pulse width and adjusting the pulse width of the internal PWM pulse signal to be equal to the predetermined allowable pulse width and generating the adjusted internal PWM pulse signal as the PWM pulse signal when the frequency of the PWM clock signal is higher than the reference frequency and the pulse width of the internal PWM pulse signal is less than the predetermined allowable pulse width. Alternatively, the generation of the PWM pulse signal may include generating the PWM pulse signal according to the data signal when the frequency of the PWM clock signal is lower than the reference frequency or when the pulse width of the PWM pulse signal to be generated according to the data signal is greater than the predetermined allowable pulse width, and calculating the data signal for allowing the pulse width of the PWM pulse signal to be equal to the predetermined allowable pulse width and generating the PWM pulse signal using the calculated data signal when the frequency of the PWM clock signal is higher than the reference frequency and the pulse width of the PWM pulse signal to be generated according to the data signal is less than the predetermined allowable pulse width.

The method may further include driving an analog circuit using the PWM pulse signal.

Exemplary embodiments of the present general inventive concept also provide a method of controlling an apparatus with a pulse width modulation (PWM), the method including setting a frequency detection signal with a detector according to whether a frequency of a detected PWM clock signal is higher than a reference frequency, generating a PWM pulse signal with a signal generator according to the frequency detection signal, the detected PWM clock signal, and a data signal, and controlling the apparatus according to the generated PWM pulse signal.

The method may include that when the frequency of the PWM clock signal is higher than the reference frequency, adjusting the minimum pulse width of an internal PWM pulse signal to be greater than predetermined allowable pulse width to generate the PWM pulse signal.

The method may include controlling the apparatus by varying one or more drive currents to the apparatus according to the generated PWM pulse signal.

The method may include setting the frequency detection signal by receiving frequency information with the detector, determining whether the frequency of the PWM clock signal is higher than the reference frequency with the detector, and outputting the frequency detection signal according to the determination result.

The method may include setting the frequency detection signal by setting a plurality of reference frequencies to set a plurality of frequency ranges with the detector, comparing the frequency of the PWM clock signal with each of the plurality of reference frequencies with the detector, determining which one of the plurality of frequency ranges the frequency of the PWM clock signal belongs to with the detector, and outputting the frequency detection signal such that the frequency detection signal includes the frequency range of the PWM clock signal.

The method may include that when the frequency detection signal includes that the frequency of the PWM clock signal is lower than the reference frequency, changing the frequency detection signal with the detector to include that the frequency of the PWM clock signal is higher than the reference frequency, and outputting the changed frequency detection signal when frequency information includes that the frequency of the PWM clock signal is higher than a first reference frequency and higher than the reference frequency.

The method may include that when the frequency detection signal includes that the frequency of the PWM clock signal is higher than the reference frequency, changing the frequency detection signal with the detector to include that the frequency of the PWM clock signal is lower than the reference frequency and outputting the changed frequency detection signal when frequency information indicates that the frequency of the PWM clock signal is lower than a second reference frequency.

Exemplary embodiments of the present general inventive concept may also provide a pulse width modulation (PWM) control circuit to control an apparatus, including a detector to set a frequency detection signal according to whether a frequency of a PWM clock signal detected by the detector is higher than a reference frequency, a signal generator to generate a PWM pulse signal according to the frequency detection signal, the detected PWM clock signal, and a data signal, and a controller to control the apparatus according to the generated PWM pulse signal.

The pulse width modulation control circuit can include where the signal generator adjusts the minimum pulse width of an internal PWM pulse signal to be greater than predetermined allowable pulse width to generate the PWM pulse signal when the frequency of the PWM clock signal is higher than the reference frequency.

The pulse width modulation control circuit can include where the controller varies one or more drive currents provided to the apparatus according to the PWM pulse signal.

The pulse width modulation control circuit can include where the detector receives frequency information, determines whether the frequency of the PWM clock signal is higher than the reference frequency, and outputs the frequency detection signal according to the determination result.

The pulse width modulation control circuit can include where the detector sets a plurality of reference frequencies to set a plurality of frequency ranges, compares the frequency of the PWM clock signal with each of the plurality of reference frequencies, determines which one of the plurality of frequency ranges the frequency of the PWM clock signal belongs to, and outputs the frequency detection signal such that the frequency detection signal includes the frequency range of the PWM clock signal.

The pulse width modulation control circuit can include that when the frequency detection signal includes that the frequency of the PWM clock signal is lower than the reference frequency, the detector changes the frequency detection signal with the detector to include that the frequency of the PWM clock signal is higher than the reference frequency, and outputs the changed frequency detection signal when frequency information includes that the frequency of the PWM clock signal is higher than a first reference frequency and higher than the reference frequency.

The pulse width modulation control circuit can include that when the frequency detection signal includes that the frequency of the PWM clock signal is higher than the reference frequency, the detector changes the frequency detection signal with the detector to include that the frequency of the PWM clock signal is lower than the reference frequency, and outputs the changed frequency detection signal when frequency information indicates that the frequency of the PWM clock signal is lower than a second reference frequency.

### BRIEF DESCRIPTION OF THE DRAWINGS

The foregoing and other features and utilities of the exemplary embodiments of the present general inventive concept will be apparent from the more particular description of embodiments of the present general inventive concept, as illustrated in the accompanying drawings in which like reference characters refer to the same parts throughout the different views. The drawings are not necessarily to scale, emphasis instead being placed upon illustrating the principles of the present general inventive concepts. In the drawings:

FIG. 1 is a construction diagram illustrating a device including a pulse width modulation (PWM) pulse generating circuit according to exemplary embodiments of the present general inventive concept;

FIG. 2 is a construction diagram illustrating a detector of the device including the PWM pulse generating circuit of FIG. 1, according to exemplary embodiments of the present genearl inventive concept;

FIG. 3 is a diagram illustrating operation of a determiner of the detector of the device including the PWM pulse generating circuit of FIG. 2, according to exemplary embodiments of the present general inventive concept;

FIG. 4 is a construction diagram illustrating a PWM controller of the device including the PWM pulse generating circuit of FIG. 1, according to exemplary embodiments of the present general inventive concept;

FIG. 5 is a construction diagram illustrating a PWM controller of the device including the PWM pulse generating circuit of FIG. 1, according to exemplary embodiments of the present general inventive concept;

FIG. 6 is a flowchart illustrating a PWM control method according to exemplary embodiments of the present general inventive concept;

FIG. 7 is a flowchart illustrating an operation of setting a frequency detection signal in the PWM control method of FIG. 6, according to exemplary embodiments of the present general inventive concept;

FIG. 8 is a flowchart illustrating an operation of generating a PWM pulse signal in the PWM control method of FIG. 6, according to exemplary embodiments of the present general inventive concept; and

FIG. 9 is a flowchart illustrating an operation of generating a PWM pulse signal in the PWM control method of FIG. 6, according to other embodiments of the inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing exemplary embodiments only and is not intended to be limiting of the present general inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present general inventive concept are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, the exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

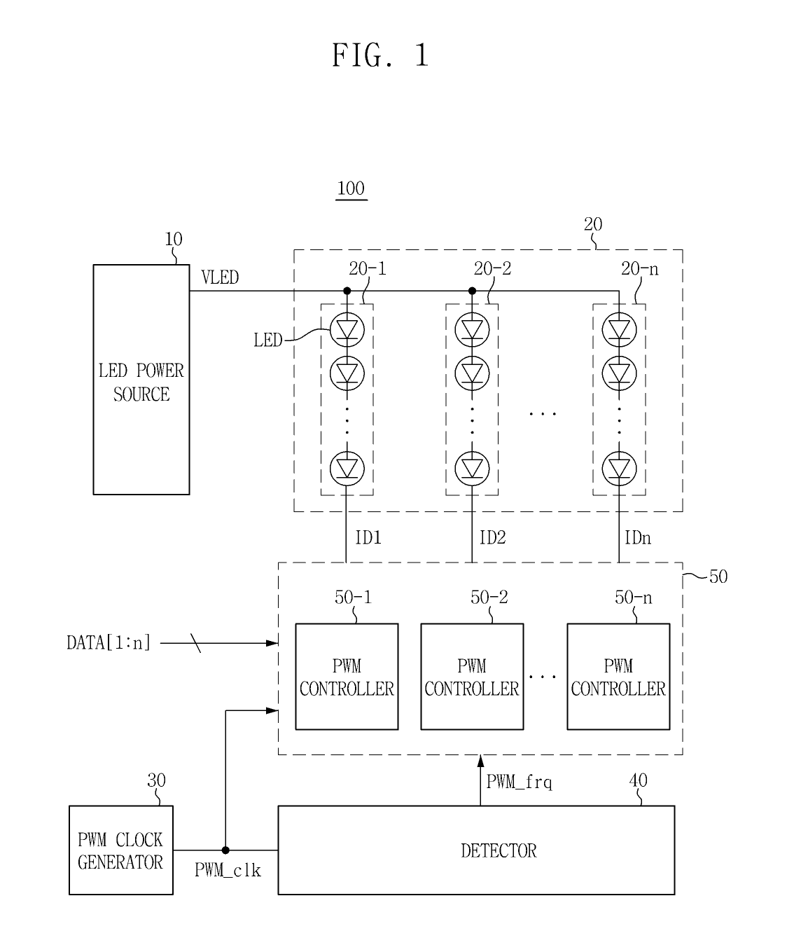

FIG. 1 is a construction diagram illustrating a device 100 including a PWM pulse generating circuit according to exemplary embodiments of the present general inventive concept, which may include a backlight unit (BLU) 20 having at least one light emitting diode (LED). In exemplary embodiments of the present general inventive concept, the device 100 may be a display to display images onto a display screen according to one or more received image signals. The BLU 20 having the at least one LED may operate when an image is displayed on the display screen of the display according to the one or more received image signals.

Referring to FIG. 1, the device 100 may include an LED power source 10, the BLU 20, a PWM clock generator 30, a detector 40, and a PWM driver 50. The BLU 20 may include at least one LED string (e.g., one or more LEDs arranged in predetermined linear direction). For example, LED strings 20-1, 20-2, . . . , and 20-n, may each include at least one LED. The PWM driver 50 may include at least one PWM controller, for example, PWM controllers 50-1, 50-2, . . . , and 50-n.

The operation of the device 100 illustrated in FIG. 1 will now be described.

The LED power source 10 may supply an LED power supply voltage VLED to the BLU 20.

The BLU 20 may receive the LED power supply voltage VLED and may be controlled according to driving currents ID1, ID2, . . . , and IDn, which are varied by the PWM driver 50. For example, the BLU 20 may receive the LED power supply voltage VLED as a power supply voltage and vary its own brightness according to the driving currents ID1, ID2, . . . , and IDn. Each of the LED strings 20-1, 20-2, . . . , and 20-n may receive the LED power supply voltage VLED and vary its own brightness according to the corresponding one of the driving currents ID1, ID2, . . . , and IDn.

The PWM clock generator 30 may generate a PWM clock signal PWM_clk. The frequency of the PWM clock signal may be in the range of about 51 kHz to 5.1 MHz. The frequency of the PWM clock signal may be adjusted. For example, the frequency of the PWM clock signal may be adjusted by an external resistor and/or by a control signal from an external controller.

The detector 40 may output a frequency detection signal PWM_frq according to the PWM clock signal PWM_clk output from the PWM clock generator 30. The detector 40 may output the frequency detection signal PWM_frq according to whether the frequency of the PWM clock signal PWM_clk is higher than a predetermined reference frequency. The detector 40 may have hysteresis characteristics. In a state where it is determined that the frequency of the PWM clock signal PWM_clk is lower than the reference frequency, and when the frequency of the PWM clock signal PWM_clk becomes higher than a first reference frequency and higher than the reference frequency, the detector 40 may output the frequency detection signal PWM_frq to indicate that the frequency of the PWM clock signal PWM_clk is higher than the reference frequency. In a state where it is determined that the frequency of the PWM clock signal PWM_clk is higher than the reference frequency, and when the frequency of the PWM clock signal PWM_clk becomes lower than a second reference frequency and lower than the reference frequency, the detector 40 may output the frequency detection signal PWM_frq to indicate that the frequency of the PWM clock signal PWM_clk is lower than the reference frequency. The detector 40 may output the frequency detection signal PWM_frq to indicate that the frequency of the PWM clock signal PWM_clk is lower than the reference frequency.

The PWM driver 50 may vary driving currents ID1, ID2, . . . , and IDn according to a data signal DATA[1:n], a PWM clock signal PWM_clk, and a frequency detection signal PWM_frq.

Each of the PWM controllers 50-1, 50-2, . . . , and 50-n may vary the corresponding one of the driving currents ID1, ID2, . . . , and IDn according to the corresponding one of the data signals DATA[1:n], the PWM clock signal PWM_clk, and the frequency detection signal PWM_frq.

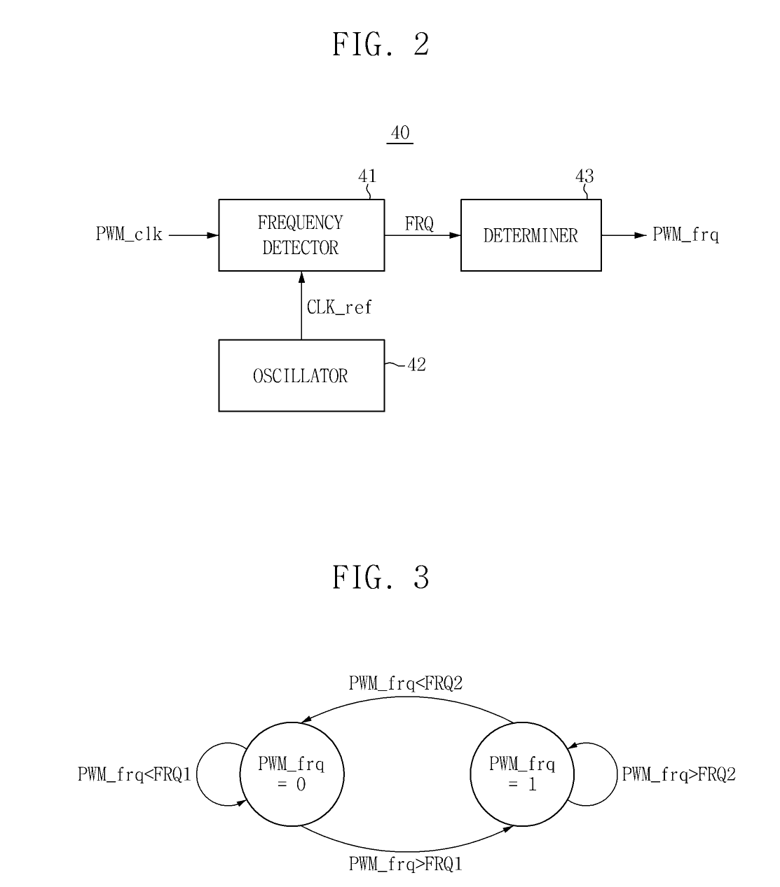

FIG. 2 is a construction diagram illustrating the detector 40 of the device 100 including the PWM pulse generating circuit of FIG. 1. Referring to FIG. 2, the detector 40 may include a frequency detector 41, an oscillator 42, and a determiner 43.

The operation of the detector 40 illustrated in FIG. 2 will now be described.

The frequency detector 41 may receive a reference clock signal CLK_ref, detect the frequency of the PWM clock signal PWM_clk output from the PWM clock generator 30, and output frequency information FRQ. For example, the frequency detector 41 may count a cycle of the PWM clock signal PWM_clk as the reference clock signal CLK_ref and output the frequency information FRQ to indicate the frequency of the PWM clock signal PWM_clk.

The oscillator 42 may generate the reference clock signal CLK_ref. The reference clock signal CLK_ref may have a higher frequency than the PWM clock signal PWM_clk. For example, when the frequency of the PWM clock signal PWM_clk fluctuates and/or varies in the range of about 51 kHz to 5.1 MHz, the reference clock signal CLK_ref may have a frequency of about 20 MHz. That is, the reference clock signal CLK_ref may have a higher frequency than the frequency of the PWM clock signal PWM_clk.

The determiner 43 may receive the frequency information FRQ, determine whether the frequency of the PWM clock signal PWM_clk is higher than the reference frequency, and output the frequency detection signal PWM_frq according to a determination result. The determiner 43 may have hysteresis characteristics and can output the frequency detection signal PWM_frq. The hysteresis characteristics of the determiner 43 may include a state where it is determined that the frequency of the PWM clock signal PWM_clk is lower than the reference frequency, and when the frequency of the PWM clock signal PWM_clk becomes higher than a first reference frequency and higher than the reference frequency, the determiner 43 may output the frequency detection signal PWM_frq to indicate that the frequency of the PWM clock signal PWM_clk is higher than the reference frequency. In a state where it is determined that the frequency of the PWM clock signal PWM_clk is higher than the reference frequency, and when the frequency of the PWM clock signal PWM_clk becomes lower than a second reference frequency and lower than the reference frequency, the determiner 43 may output the frequency detection signal PWM_frq to indicate that the frequency of the PWM clock signal PWM_clk is lower than the reference frequency.

The determiner 43 may set a plurality of reference frequencies to set a plurality of frequency ranges, compare the frequency of the PWM clock signal PWM_clk with each of the plurality of reference frequencies, determine which one of the plurality of frequency ranges the frequency of the PWM clock signal PWM_clk belongs to, and output the frequency detection signal PWM_frq such that the frequency detection signal PWM_frq indicates the frequency range of the PWM clock signal PWM_clk.

FIG. 3 is a diagram illustrating operation of the determiner 43 of the detector 40 of the device 100 including the PWM pulse generating circuit of FIG. 2, according to exemplary embodiments of the present general inventive concept.

As described above, the determiner 43 may have hysteresis characteristics, and can output the frequency detection signal PWM_frq.

The determiner 43 may output “0” as the frequency detection signal PWM_frq when the frequency of the PWM clock signal PWM_clk is lower than the reference frequency, and output “1” as the frequency detection signal PWM_frq when the frequency of the PWM clock signal PWM_clk is higher than the reference frequency. The determiner 43 may set an initial value of the frequency detection signal PWM_frq to “0”.

When the frequency detection signal PWM_frq indicates that the frequency of the PWM clock signal PWM_clk is lower than the reference frequency (i.e., PWM_frq=0), the determiner 43 may change the frequency detection signal PWM_frq to indicate that the frequency of the PWM clock signal PWM_clk is higher than the reference frequency. The determiner 43 can output the changed frequency detection signal PWM_frq when the frequency information FRQ indicates that the frequency of the PWM clock signal PWM_clk is higher than a first reference frequency FRQ1 and higher than the reference frequency. In exemplary embodiments of the present general inventive concept, the determiner 43 may not change the frequency detection signal PWM_frq when the frequency information FRQ indicates that the frequency of the PWM clock signal PWM_clk is lower than the first reference frequency FRQ1.

Conversely, in a case where the frequency detection signal PWM_frq indicates that the frequency of the PWM clock signal PWM_clk is higher than the reference frequency (i.e., PWM_frq=1), the determiner 43 may change the frequency detection signal PWM_frq to indicate that the frequency of the PWM clock signal PWM_clk is lower than the reference frequency. The determiner 43 can output the changed frequency detection signal PWM_frq when the frequency information FRQ indicates that the frequency of the PWM clock signal PWM_clk is lower than a second reference frequency FRQ2 and lower than the reference frequency. The determiner 43 may not change the frequency detection signal PWM_frq when the frequency information FRQ indicates that the frequency of the PWM clock signal PWM_clk is higher than the second reference frequency FRQ2.

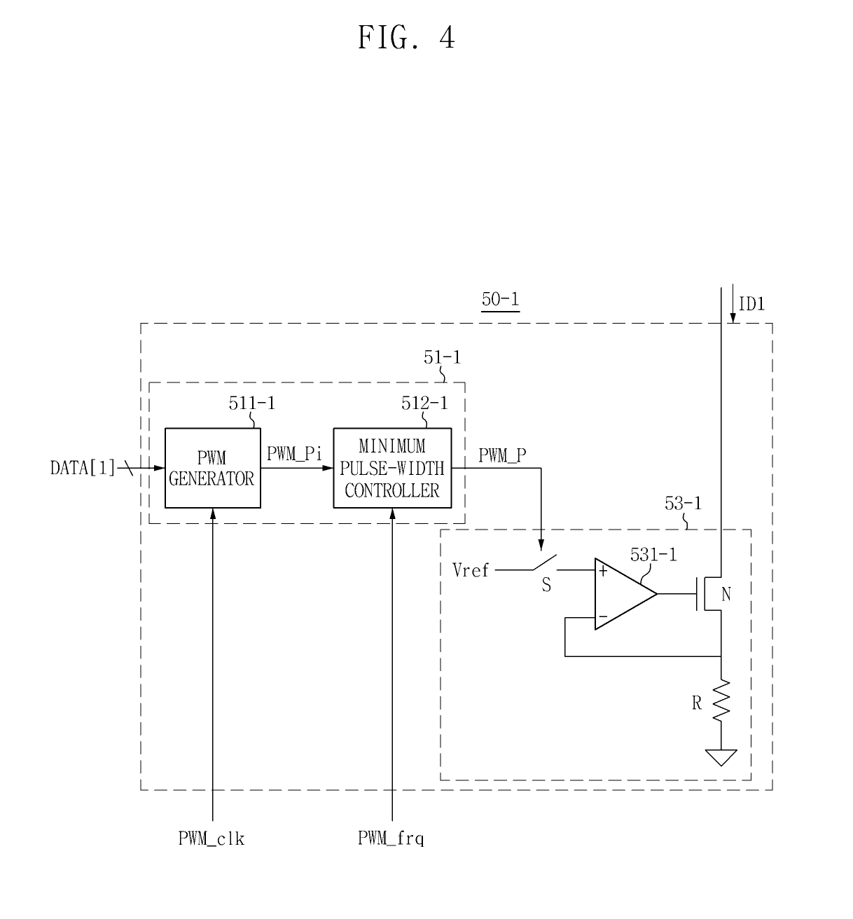

FIG. 4 is a construction diagram illustrating the PWM controller 50-1 of the PWM controllers 50-1, 50-2, . . . , and 50-n of the device 100 including the PWM pulse generating circuit of FIG. 1, according to exemplary embodiments of the present general inventive concept.

Referring to FIG. 4, the PWM controller 50-1 may include a PWM pulse signal generator 51-1 and a current driver 53-1. The PWM pulse signal generator 51-1 may include a PWM generator 511-1 and a minimum pulse-width controller 512-1, and the current driver 53-1 may include a switch S, an operational amplifier (OP-AMP) 531-1, an NMOS transistor N, and a resistor R.

The operation of the PWM controller 50-1 illustrated in FIG. 4 will now be described.

The PWM pulse signal generator 51-1 may output a PWM pulse signal PWM_P according to a data signal DATA[1], a PWM clock signal PWM_clk, and a frequency detection signal PWM_frq. Specifically, the PWM pulse signal generator 51-1 may receive the PWM clock signal PWM_clk and output the PWM pulse signal PWM_P corresponding to the data signal DATA[1]. When the frequency detection signal PWM_frq indicates that the frequency of the PWM clock signal PWM_clk is higher than the reference frequency, the PWM pulse signal generator 51-1 may adjust the pulse width of the PWM pulse signal PWM_P to a predetermined allowable pulse width or a pulse width that is higher than the predetermined allowable pulse width and output the PWM pulse signal PWM_P. That is, the PWM pulse signal generator 51-1 may adjust the pulse width to be equal to or greater than a predetermined allowable pulse width.

The frequency of the PWM pulse signal PWM_P may be determined by the frequency of the PWM clock signal PWM_clk and the bit number of the received data signal DATA[1:n]. For example, assuming that the frequency of the PWM clock signal PWM_clk is between 51 kHz to 5.1 MHz and each of the data signals DATA[1:n] is an 8-bit signal, the frequency of the PWM pulse signal PWM_P may be about 1/255 of the frequency of the PWM clock signal PWM_clk. That is, the frequency of the PWM pulse signal PWM_P may range from about 200 Hz to 20 kHz.

The PWM generator 511-1 may output an internal PWM pulse signal PWM_Pi according to the PWM clock signal PWM_clk and the corresponding data signal DATA[1] of the data signals DATA[1:n]. The PWM generator 511-1 may receive the PWM clock signal PWM_clk and output the internal PWM pulse signal PWM_Pi having a duty ratio corresponding to the data signal DATA[1]. That is, the pulse width of the internal PWM pulse signal PWM_Pi may be determined by the frequency of the PWM clock signal PWM_clk and the data signal DATA[1]. The data signal DATA[1] may be a plural-bit digital signal.

The minimum pulse-width controller 512-1 may control the minimum pulse width (i.e., a predetermined minimum pulse width) of the internal PWM pulse signal PWM_Pi according to the frequency detection signal PWM_frq and can output a PWM pulse signal PWM_P. For example, when the frequency detection signal PWM_frq indicates that the frequency of the PWM clock signal PWM_clk is lower than the reference frequency, the minimum pulse-width controller 512-1 may output the internal PWM pulse signal PWM_Pi as the PWM pulse signal PWM_P. When the frequency detection signal PWM_frq indicates that the frequency of the PWM clock signal PWM_clk is higher than the reference frequency, the minimum pulse-width controller 512-1 may adjust the minimum pulse width of the internal PWM pulse signal PWM_Pi to be equal to a predetermined allowable pulse width and output the adjusted internal PWM pulse signal PWM_Pi as the PWM pulse signal PWM_P. Specifically, when the frequency detection signal PWM_frq indicates that the frequency of the PWM clock signal PWM_clk is lower than the reference frequency or when the pulse width of the internal PWM pulse signal PWM_Pi is greater than the predetermined allowable pulse width, the minimum pulse-width controller 512-1 may output the internal PWM pulse signal PWM_Pi as the PWM pulse signal PWM_P. Alternatively, when the frequency detection signal PWM_frq indicates that the frequency of the PWM clock signal PWM_clk is higher than the reference frequency and the pulse width of the internal PWM pulse signal PWM_Pi is less than the predetermined allowable pulse width, the minimum pulse-width controller 512-1 may adjust the pulse width of the internal PWM pulse signal PWM_Pi to be equal to the predetermined allowable pulse width and output the adjusted internal PWM pulse signal PWM_Pi as the PWM pulse signal PWM_P.

A value of the predetermined allowable pulse width may be determined by the current driver 53-1 and/or a device (e.g., the BLU 20) to be controlled according to a PWM pulse signal PWM_P. The predetermined allowable pulse width may be the predetermined minimum pulse width to operate the current driver 53-1. That is, the current driver 53-1 may be an analog circuit as illustrated in FIG. 4. The PWM pulse signal PWM_P applied to the analog circuit may have at least the minimum pulse width so that the analog circuit can be normally driven. In exemplary embodiments of the present general inventive concept, the predetermined allowable pulse width may be the same as the minimum pulse width.

The reference frequency may be a frequency corresponding to the predetermined allowable pulse width. For instance, assuming that the predetermined allowable pulse width is 1 ms, the frequency of the PWM pulse signal PWM_P can be 1 kHz. Thus, when a data signal is an 8-bit signal, the predetermined reference frequency may be 255 kHz. In this case, the first reference frequency may be 270 kHz, and the second reference frequency may be 243 kHz.

The current driver 53-1 may vary the driving current ID1 according to the PWM pulse signal PWM_P. The current driver 53-1 may include a resistor R connected to a ground voltage, an NMOS transistor N connected between the resistor R and the BLU 20, a switch S to transmit a reference voltage Vref according to the PWM pulse signal PWM_P, and an OP-AMP 531-1 to compare the reference voltage Vref transmitted through the switch S with a voltage between the resistor R and the NMOS transistor N and transmit an output voltage to a gate of the NMOS transistor N.

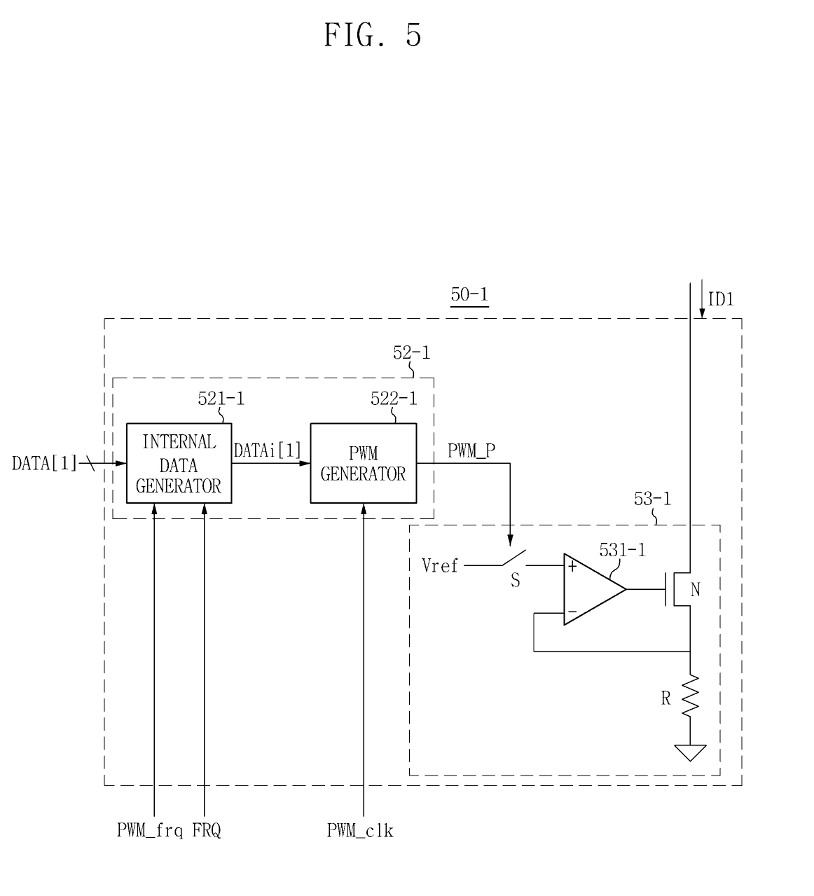

FIG. 5 is a construction diagram illustrating the PWM controller 50-1 of the PWM controllers 50-1, 50-2, . . . , and 50-n of the device 100 including the PWM pulse generating circuit of FIG. 1, according to exemplary embodiments of the present general inventive concept.

Referring to FIG. 5, the PWM controller 50-1 may include a PWM pulse signal generator 52-1 and a current driver 53-1. The PWM pulse signal generator 52-1 may include an internal data generator 521-1 and a PWM generator 522-1, and the current driver 43-1 may include a switch S, an OP-AMP 531-1, an NMOS transistor N, and a resistor R.

The operation of the PWM controller 50-1 illustrated in FIG. 5 will now be described.

The operation of the PWM pulse signal generator 52-1 may be the same as that of the PWM pulse signal generator 51-1 described with reference to FIG. 4, and the operation of the current driver 53-1 may be the same as described with reference to FIG. 4.

The internal data generator 521-1 may receive the corresponding data signal DATA[1] of the data signals DATA[1:n] and can generate an internal data signal DATAi[1] according to the frequency detection signal PWM_frq. That is, when the frequency detection signal PWM_frq indicates that the frequency of the PWM clock signal PWM_clk is lower than the reference frequency, the internal data generator 521-1 may output the data signal DATA[1] as the internal data signal DATAi[1]. When the frequency detection signal PWM_frq indicates that the frequency of the PWM clock signal PWM_clk is higher than the reference frequency, the internal data generator 521-1 may calculate the pulse width of a PWM pulse signal to be generated by the data signal DATA[1] and determine whether the calculated pulse width is less than the predetermined allowable pulse width. When the calculated pulse width is less than the predetermined allowable pulse width, the internal data generator 521-1 may calculate a data signal, so that the pulse width of the PWM pulse signal to be generated is equal to the predetermined allowable pulse width, and output the calculated data signal as the internal data signal DATAi[1]. When the calculated pulse width of the PWM pulse signal is not less than the predetermined allowable pulse width, the internal data generator 521-1 may output the data signal DATA[1] as the internal data signal DATAi[1].

To calculate the pulse width, the internal data generator 521-1 may receive frequency information FRQ of the PWM clock signal PWM_clk. The frequency information FRQ may be output by the detector 40.

Alternatively, as described above, the determiner 43 of the detector 40 may output the frequency detection signal PWM_frq such that the frequency detection signal PWM_frq indicates the frequency range of the PWM clock signal PWM_clk. In this case, the internal data generator 521-1 may receive the frequency detection signal PWM_frq and calculate the pulse width of the PWM pulse signal.

The PWM generator 522-1 may output a PWM pulse signal PWM_P according to the internal data signal DATAi[1] and the PWM clock signal PWM_clk. That is, the PWM generator 522-1 may receive the PWM clock signal PWM_clk and output the PWM pulse signal PWM_P having a duty ratio corresponding to the internal data signal DATAi[1].

One or more of the PWM controllers 50-2, . . . , and 50-n may be the same as the PWM controller 50-1 of FIG. 4 or FIG. 5 except that the corresponding data signal DATA[2], . . . , and DATA[n] is applied to the PWM generator (or internal data generator) of each of the PWM controllers 50-2, . . . , and 50-n.

Although FIGS. 1 through 5 exemplarily illustrate that each of the PWM controllers 50-1, 50-2, . . . , and 50-n of the PWM driver 50 includes the PWM pulse signal generator 51-1 or 52-1, the PWM driver 50 may include only one PWM pulse signal generator 51-1 or 52-1. In this case, each of the PWM controllers 50-1, 50-2, . . . , and 50-n may include only the current driver 53-1, only one data signal (e.g., data signal DATA[1]) may be applied to the current driver 53-1, and the same PWM pulse signal PWM_P may be applied to current drivers connected to the respective LED strings 20-1, 20-2, . . . , and 20-n.

Although FIGS. 4 and 5 exemplarily illustrate a circuit to vary a driving current according to a PWM pulse signal PWM_P as a circuit driven according to the PWM pulse signal PWM_P, the circuit driven according to the PWM pulse signal PWM_P may be an analog circuit according to exemplary embodiments of the present general inventive concept as disclosed herein.

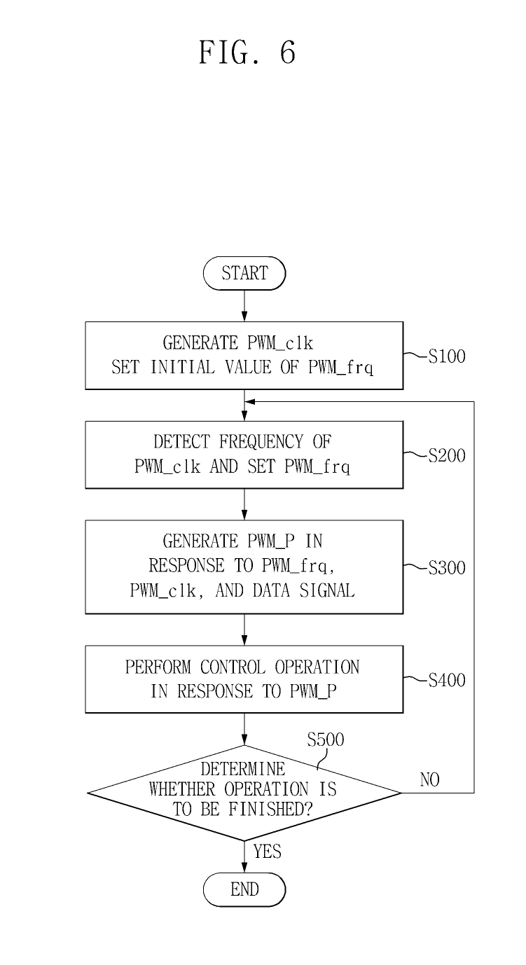

FIG. 6 is a flowchart illustrating a PWM control method according to exemplary embodiments of the present general inventive concept.

A control method using a PWM pulse according to exemplary embodiments of the present general inventive concept will now be described with reference to FIG. 6.

A PWM clock signal PWM_clk may be generated, and an initial value of a frequency detection signal PWM_frq may be set at operation S100.

The frequency of the PWM clock signal PWM_clk may be detected to set the frequency detection signal PWM_frq at operation S200. That is, the frequency detection signal PWM_frq may be set depending on whether the frequency of the PWM clock signal PWM_clk is higher than the reference frequency. Operation S200 will be described in detail later.

A PWM pulse signal PWM_P may be generated according to a frequency detection signal PWM_frq, a PWM clock signal PWM_clk, and a data signal at operation S300. Specifically, the PWM clock signal PWM_clk may be input to generate an internal PWM pulse signal having a duty ratio corresponding to the data signal. Thus, when the frequency detection signal PWM_frq indicates that the frequency of the PWM clock signal PWM_clk is higher than the reference frequency, the minimum pulse width of the internal PWM pulse signal may be adjusted to be greater than predetermined allowable pulse width to generate the PWM pulse signal PWM_P. Operation S300 will be described in detail later.

A control operation may be performed according to the PWM pulse signal PWM_P at operation S400 by driving an analog circuit according to the PWM pulse signal PWM_P. For example, as illustrated in FIGS. 1 and 2, when the BLU 20 is controlled using the PWM pulse signal PWM_P, the driving currents ID1, ID2, . . . , and IDn may be varied according to the PWM pulse signal PWM_P in the control operation.

It may be determined whether the operation is to be finished, and operations S200 through S400 may be repeated or the operation may be finished based on a determination result at operation S500.

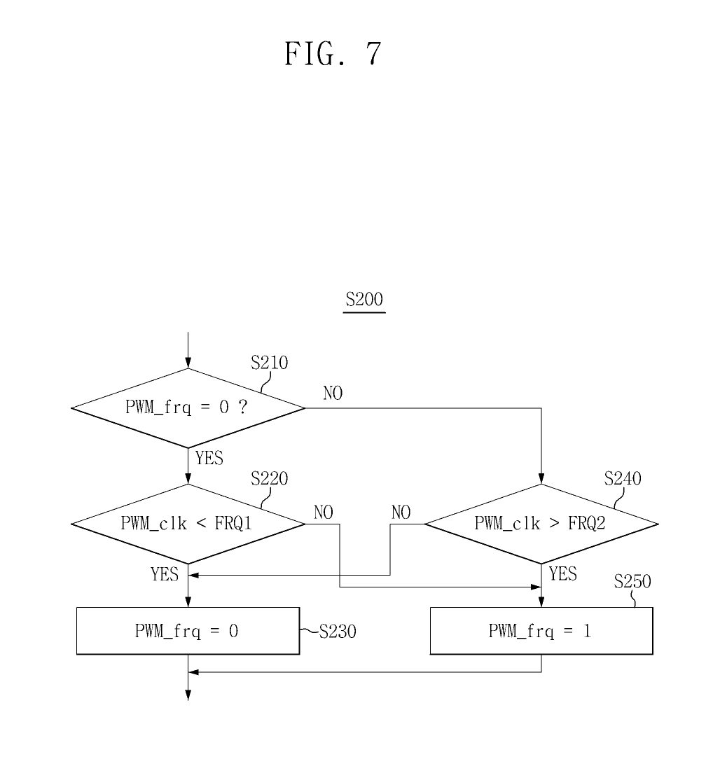

FIG. 7 is a flowchart illustrating an operation of setting the frequency detection signal PWM_frq (operation S200) in the PWM control method of FIG. 6, according to exemplary embodiments of the present general inventive concept. Specifically, it is assumed in FIG. 7 that the frequency detection signal PWM_frq having a value of “0” indicates that the frequency of the PWM clock signal PWM_clk is lower than the reference frequency, the frequency detection signal PWM_frq having a value of “1” indicates that the frequency of the PWM clock signal PWM_clk is higher than the reference frequency, and an initial value of the frequency detection signal PWM_frq is set to “0” in operation S100.

The setting of the frequency detection signal PWM_frq (operation S200) will now be described with reference to FIG. 7.

It may be determined whether the frequency detection signal PWM_frq has an initial value of “0” or not at operation S210. That is, it may be determined whether the frequency of the current PWM clock signal PWM_clk is higher or lower than the reference frequency.

When it is determined in operation S210 that the frequency detection signal PWM_frq is not “0,” it may be determined whether the frequency of the PWM clock signal PWM_clk is lower than a first reference frequency FRQ1 and higher than the reference frequency at operation S220. In exemplary embodiments of the present general inventive concept, the first reference frequency FRQ1 may be higher than the reference frequency.

When it is determined in operation S220 that the frequency of the PWM clock signal PWM_clk is lower than the first reference frequency FRQ1, the frequency detection signal PWM_frq may be set to “0” at operation S230. In other words, the frequency detection signal PWM_frq may not be varied.

When it determined in operation S220 that the frequency of the PWM clock signal PWM_clk is not lower than the first reference frequency FRQ1, the frequency detection signal PWM_frq may be set to “1” at operation S250. In other words, the frequency detection signal PWM_frq may be varied.

When it is determined in step S210 that the frequency detection signal PWM_frq is not “0,” that is, when the frequency detection signal PWM_frq is “1,” it may be determined whether the frequency of the PWM clock signal PWM_clk is higher than a second reference frequency FRQ2 and lower than the reference frequency at operation S240. In exemplary embodiments of the present general inventive concept, the second reference frequency FRQ2 may be lower than the reference frequency.

When it is determined in operation S240 that the frequency of the PWM clock signal PWM_clk is higher than the second reference frequency FRQ2, the frequency detection signal PWM_frq may be set to “1” at operation S250. In other words, the frequency detection signal PWM_frq may not be varied.

When it is determined in step S240 that the frequency of the PWM clock signal PWM_clk is not higher than the second reference frequency FRQ2, the frequency detection signal PWM_frq may be set to “0” at operation S230. In other words, the frequency detection signal PWM_frq may be varied.

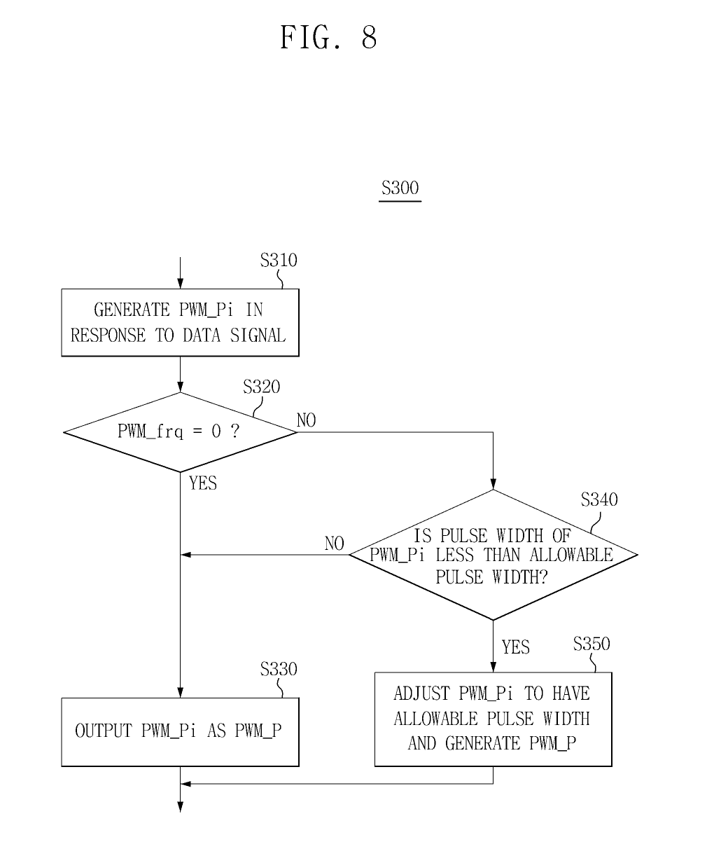

FIG. 8 is a flowchart illustrating an operation of generating the PWM pulse signal PWM_P (operation S300) in the PWM control method of FIG. 6, according to exemplary embodiments of the present general inventive concept.

The generation of the PWM pulse signal PWM_P (operation S300) according to exemplary embodiments of the present general inventive concept will now be described with reference to FIG. 8.

An internal PWM pulse signal PWM_Pi may be generated according to the corresponding data signal DATA[1:n] at operation S310. That is, the PWM clock signal PWM_clk may be input to generate an internal PWM pulse signal PWM_Pi having a duty ratio corresponding to the data signal.

It may be determined whether a frequency detection signal PWM_frq is “0” or not at operation S320. That is, it may be determined whether the frequency of the PWM clock signal PWM_clk is higher than the reference frequency.

As a result, when it is determined in operation S320 that the frequency detection signal PWM_frq is “0,” that is, when the frequency of the PWM clock signal PWM_clk is lower than the reference frequency, the internal PWM pulse signal PWM_Pi may be output as the PWM pulse signal PWM_P.

When it is determined in operation S320 that the frequency detection signal PWM_frq is not “0”, that is, when the frequency of the PWM clock signal PWM_clk is higher than the reference frequency, it may be determined whether the pulse width of the internal PWM pulse signal PWM_Pi is less than a predetermined allowable pulse width at operation S340. Here, the allowable pulse width may be determined by the current driver 43-1 and/or a device (e.g., BLU 20) to be controlled according to the PWM pulse signal PWM_P.

When it is determined in step S340 that the pulse width of the internal PWM pulse signal PWM_Pi is not less than the predetermined allowable pulse width, the internal PWM pulse signal PWM_Pi may be output as the PWM pulse signal PWM_P at operation S330.

When it is determined in step S340 that the pulse width of the internal PWM pulse signal PWM_Pi is less than the predetermined allowable pulse width, the pulse width of the internal PWM pulse signal PWM_Pi may be adjusted to the predetermined allowable pulse width, and the adjusted internal PWM pulse signal PWM_Pi may be output as the PWM pulse signal PWM_P.

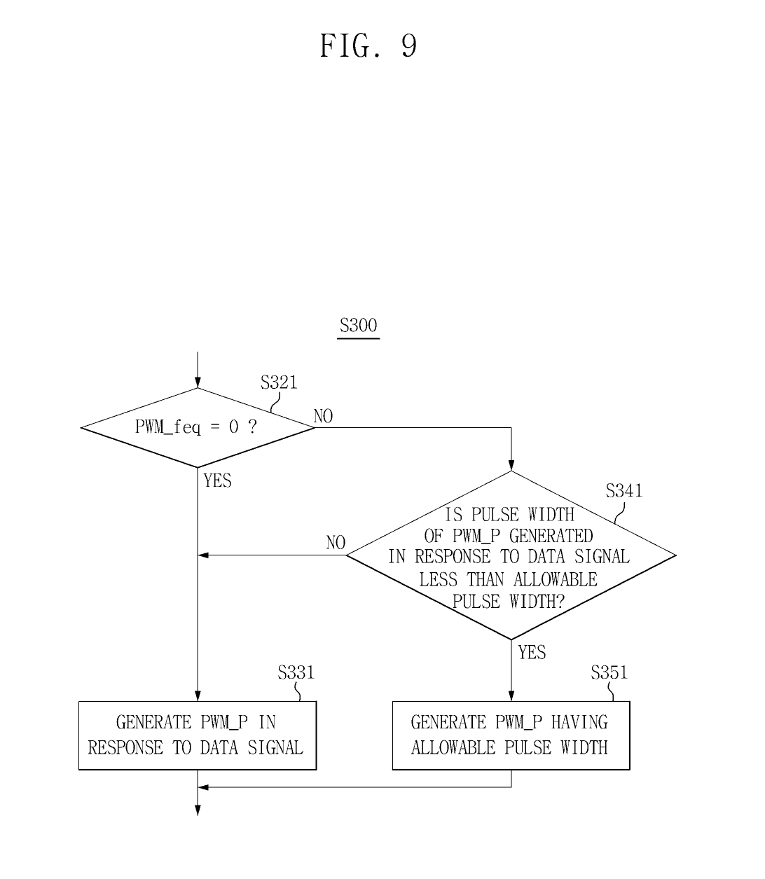

FIG. 9 is a flowchart illustrating the generation of the PWM pulse signal PWM_P ( operation S300) in the PWM control method of FIG. 6, according to exemplary embodiments of the present general inventive concept.

The generation of the PWM pulse signal PWM_P (operation S300) according to exemplary embodiments of the present general inventive concept will now be described with reference to FIG. 9.

It may be determined whether the frequency detection signal PWM_frq is “0” or not at operation S321. That is, it may be determined whether the PWM clock signal PWM_clk is higher than the reference frequency.

When it is determined in step S321 that the frequency detection signal PWM_frq is “0,” that is, when the frequency of the PWM clock signal PWM_clk is lower than the reference frequency, the PWM pulse signal PWM_P may be generated according to a data signal (operation S331).

When it is determined in operation S321 that the frequency detection signal PWM_frq is not “0,” that is, when the frequency of the PWM clock signal PWM_clk is higher than the reference frequency, it may be determined whether the pulse width of the PWM pulse signal PWM_P generated according to the data signal is less than an allowable pulse width at operation S341.

When it is determined in operation S341 that the pulse width of the PWM pulse signal PWM_P generated according to the data signal is not less than the allowable pulse width, the PWM pulse signal PWM_P may be generated according to the data signal in operation S331.

When it is determined in step S341 that the pulse width of the PWM pulse signal PWM_P generated according to the data signal is less than the predetermined allowable pulse width, the PWM pulse signal PWM_P having a pulse width equal to the predetermined allowable pulse width may be generated operation S351. For example, the PWM pulse signal PWM_P generated according to a data signal to have the predetermined allowable pulse width. That is, the data signal may be calculated, and the PWM pulse signal PWM_P may be generated using the calculated data signal.

Although a display device including a BLU has been explained thus far as an example of a device including a PWM pulse generating circuit according to embodiments of the inventive concept, the inventive concept may be applied to any other device including a PWM pulse generating circuit.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

Although several embodiments of the present invention have been illustrated and described, it would be appreciated by those skilled in the art that changes may be made in these embodiments without departing from the principles and spirit of the general inventive concept, the scope of which is defined in the claims and their equivalents.

What is claimed is:

1. A pulse width modulation (PWM) circuit comprising:
a detector to detect the frequency of a PWM clock signal and to output a frequency detection signal including whether the frequency of the PWM clock signal is higher than a reference frequency; and
a PWM pulse signal output unit to generate a PWM pulse signal according to a data signal, the PWM clock signal, and the frequency detection signal,
wherein when the frequency detection signal indicates that the frequency of the PWM clock signal is higher than the reference frequency, the PWM pulse signal output unit generates the PWM pulse signal having a predetermined allowable pulse width or a pulse width that is higher than the predetermined allowable pulse width.

2. The circuit of claim 1, wherein the detector comprises:
an oscillator to generate a reference clock signal;
a frequency detector to count the reference clock signal according to the PWM clock signal and to output frequency information on the PWM clock signal; and
a determiner to receive the frequency information, compare the frequency information with the reference frequency, and output the frequency detection signal.

3. The circuit of claim 2, wherein the determiner determines that the frequency of the PWM clock signal is higher than the reference frequency when the frequency of the PWM clock signal becomes higher than a first reference frequency and higher than the reference frequency in a state where the frequency of the PWM clock signal is lower than the reference frequency,
the determiner determines that the frequency of the PWM clock signal is lower than the reference frequency when the frequency of the PWM clock signal becomes lower than a second reference frequency and lower than the reference frequency in a state where the frequency of the PWM clock signal is higher than the reference frequency, and
the determiner outputs the frequency detection signal according to the determination result.

4. The circuit of claim 2, wherein the determiner sets a plurality of reference frequencies to set a plurality of frequency ranges, compares the frequency information with each of the plurality of reference frequencies, and outputs the frequency detection signal that includes which one of the plurality of frequency ranges the frequency of the PWM clock signal belongs.

5. The circuit of claim 1, wherein the PWM pulse signal output unit comprises:
a PWM generator to receive the PWM clock signal and to output an internal PWM pulse signal having a duty ratio corresponding to the data signal; and
a minimum pulse-width controller to output the internal PWM pulse signal as the PWM pulse signal when the frequency detection signal indicates that the frequency of the PWM clock signal is lower than the reference frequency or when the pulse width of the internal PWM pulse signal is greater than the predetermined allowable pulse width, adjust the pulse width of the internal PWM pulse signal to be equal to the predetermined allowable pulse width and output the adjusted internal PWM pulse signal as the PWM pulse signal when the frequency detection signal indicates that the frequency of the PWM clock signal is higher than the reference frequency and the pulse width of the internal PWM pulse signal is less than the predetermined allowable pulse width, and output the PWM pulse signal.

6. The circuit of claim 1, wherein the PWM pulse signal output unit comprises:
an internal data generator to output the data signal as an internal data signal when the frequency detection signal indicates that the frequency of the PWM clock signal is lower than the reference frequency or when the pulse width of the PWM pulse signal to be generated according to the data signal is greater than the predetermined allowable pulse width, and calculate the data signal so that the pulse width of the PWM pulse signal is equal to the predetermined allowable pulse width and output the calculated data signal as the internal data signal when the frequency detection signal includes that the frequency of the PWM clock signal is higher than the reference frequency and the pulse width of the PWM pulse signal to be generated according to the data signal is less than the predetermined allowable pulse width; and
a PWM generator to receive the PWM clock signal and to generate the PWM pulse signal having a duty ratio corresponding to the internal data signal.

7. The circuit of claim 1, further comprising:
a PWM clock generator to generate the PWM clock signal.

8. The circuit of claim 1, further comprising:
a controller to control an apparatus according to the generated PWM pulse signal.

9. The circuit of claim 8, wherein the controller varies one or more drive currents provided to the apparatus according to the PWM pulse signal.

10. The circuit of claim 1, wherein the detector receives frequency information, determines whether the frequency of the PWM clock signal is higher than the reference frequency, and outputs the frequency detection signal according to the determination result.

11. The circuit of claim 1, wherein the detector sets a plurality of reference frequencies to set a plurality of frequency ranges, compares the frequency of the PWM clock signal with each of the plurality of reference frequencies, determines which one of the plurality of frequency ranges the frequency of the PWM clock signal belongs to, and outputs the frequency detection signal such that the frequency detection signal includes the frequency range of the PWM clock signal.

12. A device comprising:
a pulse width modulation (PWM) clock generator to generate a PWM clock signal;
a detector to detect the frequency of the PWM clock signal and to output a frequency detection signal including whether the frequency of the PWM clock signal is higher than a reference frequency;
a PWM pulse signal output unit to generate a PWM pulse signal according to a data signal, the PWM clock signal, and the frequency detection signal; and
an analog circuit to be driven according to the PWM pulse signal,
wherein when the frequency detection signal includes that the frequency of the PWM clock signal is higher than the reference frequency, the PWM pulse signal output unit generates the PWM pulse signal having a predetermined allowable pulse width or a pulse width that is higher than the predetermined allowable pulse width.

13. The device of claim 12, further comprising:
a backlight unit (BLU) including at least one light emitting diode (LED); and
an LED power source to supply a power supply voltage to the at least one LED.

14. The device of claim 13, wherein the analog circuit varies a driving current supplied to the at least one LED according to the PWM pulse signal.

15. A method of controlling an apparatus with a pulse width modulation (PWM), the method comprising:
setting a frequency detection signal with a detector according to whether a frequency of a detected PWM clock signal is higher than a reference frequency;
generating a PWM pulse signal with a signal generator according to the frequency detection signal, the detected PWM clock signal, and a data signal; and
controlling the apparatus according to the generated PWM pulse signal.

16. The method of claim 15, wherein when the frequency of the PWM clock signal is higher than the reference frequency, adjusting the minimum pulse width of an internal PWM pulse signal to be greater than predetermined allowable pulse width to generate the PWM pulse signal.

17. The method of claim 15, wherein the setting the frequency detection signal comprises:
receiving frequency information with the detector;
determining whether the frequency of the PWM clock signal is higher than the reference frequency with the detector; and
outputting the frequency detection signal according to the determination result.

18. The method of claim 15, wherein the setting the frequency detection signal comprises:
setting a plurality of reference frequencies to set a plurality of frequency ranges with the detector;
comparing the frequency of the PWM clock signal with each of the plurality of reference frequencies with the detector;
determining which one of the plurality of frequency ranges the frequency of the PWM clock signal belongs to with the detector; and
outputting the frequency detection signal such that the frequency detection signal includes the frequency range of the PWM clock signal.

19. The method of claim 18, further comprising:
when the frequency detection signal includes that the frequency of the PWM clock signal is lower than the reference frequency, changing the frequency detection signal with the detector to include that the frequency of the PWM clock signal is higher than the reference frequency;
and outputting the changed frequency detection signal when frequency information includes that the frequency of the PWM clock signal is higher than a first reference frequency and higher than the reference frequency.

20. The method of claim 18, further comprising:
when the frequency detection signal includes that the frequency of the PWM clock signal is higher than the reference frequency, changing the frequency detection signal with the detector to include that the frequency of the PWM clock signal is lower than the reference frequency; and
outputting the changed frequency detection signal when frequency information indicates that the frequency of the PWM clock signal is lower than a second reference frequency.
